(19) United States
(12) Patent Application Publication
(10) Pub. No.: US 2007/0025040 A1
(43) Pub. Date: Feb. 1, 2007

(54) High voltage over-current protection device and manufacturing method thereof

(76) Inventors: Tong Cheng Tsai, Tainan City (TW); Fu Hua Chu, Taipei City (TW); Shau Chew Wang, Taipei City (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/332,294

(22) Filed: Jan. 17, 2006

(30) Foreign Application Priority Data
Jul. 27, 2005 (TW) 094125387

(51) Int. Cl. H02H 3/20; H05K 3/20

(52) U.S. Cl. 361/91.1; 29/830; 29/831; 361/88

(57) ABSTRACT

The present invention is to provide a high voltage over-current protection device and a manufacturing method thereof, in which PTC polymers are cross-linked by chemical cross-linking. With the method of the present invention, the high voltage endurance of the PTC devices is enhanced. In addition, the internal stress and degradation of polymers caused by irradiation treatment are prevented.

### BACKGROUND OF THE INVENTION

1. Field of the Invention

The present invention relates to a high voltage over-current protection device and a manufacturing method thereof and more particularly, to a high voltage over-current protection device exhibiting positive temperature coefficient (PTC) behavior and a manufacturing method thereof.

2. Description of the Prior Art

The resistance of a conventional PTC device is sensitive to temperature change. When a PTC device operates at room temperature, its resistance remains at a low value so that the circuit elements can operate normally. However, if an over-current or an over-temperature situation occurs, the resistance of the PTC device will immediately increase at least ten thousand times (over 10⁴ ohm) to a high resistance state. Therefore, the over-current will be counterchecked and the objective of protecting the circuit elements or batteries is achieved. Because the PTC device can be used to protect electronic applications effectively, it has been commonly integrated into various circuits to prevent over-current damage.

In U.S. Pat. Nos. 5,227,946 and 5,195,013, the PTC devices are disclosed, which comprises the polymers after irradiation treatment to enhance the physical cross-linking and electrical properties. As a result, the high voltage endurance of the PTC devices can be improved.

Nevertheless, the polymer will decompose into small molecules due to degradation after high dosage irradiation treatment and it will thus lose its original physical and electrical properties. In comparison with the electron beam irradiation, the gamma ray (cobalt-60) irradiation takes much longer time to irradiate the PTC device to obtain high dosage due to its inherent low irradiation energy. As a result, the throughput decreases. If an electron beam (E-bean) is used for irradiation, the high energy could shorten the irradiation time. However, it could also result in high temperature generated in the PTC and cause polymer degradation, bubble formation, and high-internal stress. Other disadvantages of E-beam are its high manufacturing cost, low penetration capability, less uniform manufacturing processing, and thus poor product quality.

### SUMMARY OF THE INVENTION

The objective of the present invention is to provide a high voltage over-current protection device and a manufacturing method thereof, in which PTC polymers are cross-linked by chemical cross-linking. With the method of the present invention, the high voltage endurance of the PTC devices is enhanced. In addition, the internal stress and degradation of polymers caused by irradiation treatment are prevented.

In order to achieve the above objective, the present invention discloses a high voltage over-current protection device comprising a chemical cross-linking PTC substrate and two metal foils. The chemical cross-linking PTC substrate is formed by laminating a stacked polymer layer containing a plurality of polymer substrates, during which an in-situ chemical cross-lining reaction occurs. The two metal foils connect to a power a power source and are configured to allow a current to flow through the chemical cross-linking PTC substrate.

A partially chemical cross-linking treatment is performed to form the polymer substrates, which comprises two steps: (1) blending; and (2) laminating. During the step of blending, a first polymer with a first functional group, a second polymer with a second functional group, conductive carbon black and other fillers (for example, magnesium hydroxide or talc) are fed into a blender. With controlled process conditions (temperature, rotational speed of the blender and time) of blending, the reaction rate of the first polymer and the second polymer is thus controlled. For example, the operation temperature of blending can be set above the softening point of the polymers to control the reaction rate of the polymers and then to form a polymer mixture that is a copolymer with a first degree of cross-linking and exhibits the property of crystalline thermoplastics.

The first polymer is selected from the group consisting of urea formaldehyde, melamine resin, bismaleimide triazine (BT), silicone plastics, random copolymer of ethylene and glycidyl methacrylate, epoxide grafted polymers and epoxide-copolymerized polymer. The first functional group is selected from the group consisting of amino group, aldehyde group, alcohol group, epoxide group and halide group.

The second polymer is selected from the group consisting of ethylene acrylic acid copolymer, acrylic acid grafted polyethylene, maleic anhydride grafted polyethylene, maleic anhydride copolymerized polyethylene, maleic anhydride grafted polypropylene, maleic anhydride copolymerized polypropylene, phenolic resin, unsaturated polyester resin and polysulfide resin. The second functional group is selected from the group consisting of acidic group, acid anhydride group and phenol group.

After the step of blending, the step of laminating is to laminate the polymer mixture at a temperature, higher than the softening point aforementioned, to form a plurality of polymer substrates with a second degree of cross-linking. The polymer mixture is laminated at a temperature between 120° C. and 250° C. and is laminated between 0.5 hour and 24 hours. The operation temperature and time are dependent on the compositions of the first polymer and the second polymer and the reaction temperature thereof. Because of higher temperature during forming the polymer substrate, the second degree of cross-linking is larger than the first degree of cross-linking. The thickness of the polymer substrate changes upon request and is between 0.1 mm and 4 mm. Each polymer substrate exhibits similar resistivity after proper processing conditions. Also, various polymer substrates with desired resistively can be achieved by tuning specific recipes.

After the partially chemical cross-linking treatment, the plurality of polymer substrates are stacked and laminated to form a stacked polymer layer and then the stacked polymer layer is sandwiched in between two metal foils. Then, the two metal foils and the stacked polymer layer are laminated to form a chemical cross-linking PTC substrate. The two laminating steps aforementioned can be combined into one, that is, first, stacking the at least one polymer substrate and then sandwiching the plurality of polymer substrates to the two metal foils and finally laminating the plurality of polymer substrates and the two metal foils to form the chemical cross-linking PTC substrate. In the present invention, the total thickness of the chemical cross-linking PTC substrate is under 10 mm, and the number of the plurality of polymer substrates is between 2 and 10.

In addition, to enhance the high voltage endurance of the chemical cross-linking PTC substrate, we can add chemical cross-linking inhibitors and promoters when blending the polymers. The chemical cross-linking inhibitor and promoters are listed as follows.

(1) initiators including anionic initiator (e.g. piperidine, phenol and 2-ethyl-4-methyl-imidzole) and cationic initiator (boron trifluoride, BF₃-amine complex, PF₅ and trifluoromethanesulfonic acid);

(2) catalysts including ammonium salt (e.g. ethyl triphenyl ammonium bromide), phosphonium salt (e.g. triethyl methyl phosphonium acetate), metal aldoxides (e.g. aluminum isopropoxide), latent catalyst (e.g. crystalline amine, core-shell polymer with amine core, high dissociation temperature peroxide or azo compound);

(3) dispersion agents including polyethylene wax, stearic acid, zinc stearate and low molecular weight acrylate copolymer;

(4) coupling agents including aminosilane, epoxysilane and mercaptosilane;

(5) flame retardants including Halogen or Phosphorus retardant, metal hydroxide (e.g. Al₂(OH)₃ or Mg(OH)₂) and metal oxide (e.g. ZnO or Sb₂O₃);

(6) plasticizers including dibasic ester (e.g. dimethyl succinate, dibutyl phthalate, dimethyl glutarate or dimethyl adipate);

(7) organic or inorganic fillers including talc, kaolin, SiO₂ and polymer fluoride powder; and

(8) antioxidants, e.g. pentaerythrityl-tetrakis [3-(3,5-di-tertbutyl-4-hydroxy-phenyl)-propionate.

To further enhance chemical cross-linking degree of the chemical cross-linking PTC substrate, a step of heat treatment is performed. The heat treatment often takes 1 to 24 hours with the temperature equal to or less than 270° C. The temperature of the step of heat treatment depends on the reaction temperatures of the first functional group and the second functional group, and it is usually above the operation temperature of the step of laminating. After that, the chemical cross-linking PTC substrate is punched by mold cutting or is cut by diamond saw cutting to form a plurality of chemical cross-linking PTC chips with smaller area. Using diamond saw cutting prevents stress-concentrated region around the cutting edge of the chemical cross-linking PTC device, which results from mold cutting. Furthermore, using diamond saw cutting prevents degradation of the high voltage endurance. Finally, the metal terminals are connected to the two metal foils by reflow process and then the high voltage over-current protection device of the present invention is completed.

The above high voltage over-current protection device and the chemical cross-linking PTC substrate exhibit the property of high voltage endurance. If the two metal foils of the high voltage over-current protection device are connected to a power source, the voltage across each two-millimeter thickness of the chemical cross-linking PTC substrate is up to 600V. That is, every two-millimeter thickness of the chemical cross-linking PTC substrate can sustain a voltage of 600V and the thicker the chemical cross-linking PTC substrate is, the higher voltage it can sustain.

The advantages of the manufacturing method of the high voltage over-current protection device of the present invention over those of conventional methods using radiation are: (1) No degradation of polymers caused by irradiation treatment was observed. On the contrary, the PTC material is tougher by using chemical cross-linking laminating method of the present invention than conventional irradiation method due to no polymer degradation; (2) To achieve cross-linking level equivalent to or above 50 Mrad irradiation dosage, it takes much less cross-linking time by chemical cross-link laminating method of the present invention than by conventional irradiation treatment. And thus, the throughput is drastically increased; (3) Irradiation uniformity issue occurs along the whole thickness of the PTC sample since the irradiation intensity decreases with increasing thickness of the material due to the shielding effect from the metal electrode and PTC matrix. This issue is eliminated by the manufacturing method of the present invention; (4) Local high temperature spot caused material damage by E-beam irradiation could be eliminated by present invention. Under E-beam irradiation, the temperature of PTC material should be strictly controlled below 85° C. to prevent undesirable local auto-acceleration chain scission of polymer molecule. However, the process conditions of the manufacturing method of the present invention are not limited by the temperature (below 85° C.) mentioned above and thus the temperature control is less critical to the material quality; and (5) With more uniform cross-link PTC material prepared by the chemical cross-linking process of the present invention rather than by the conventional irradiation method, the current density inside the high voltage over-current protection device under high voltage is more uniform. As a result, the higher voltage endurance could be achieved by the present invention.

### BRIEF DESCRIPTION OF THE DRAWINGS

The invention will be described according to the appended drawings in which:

FIGS. 1-3 illustrate an embodiment of the high voltage over-current protection device manufacturing method of the present invention.

### DETAILED DESCRIPTION OF THE INVENTION

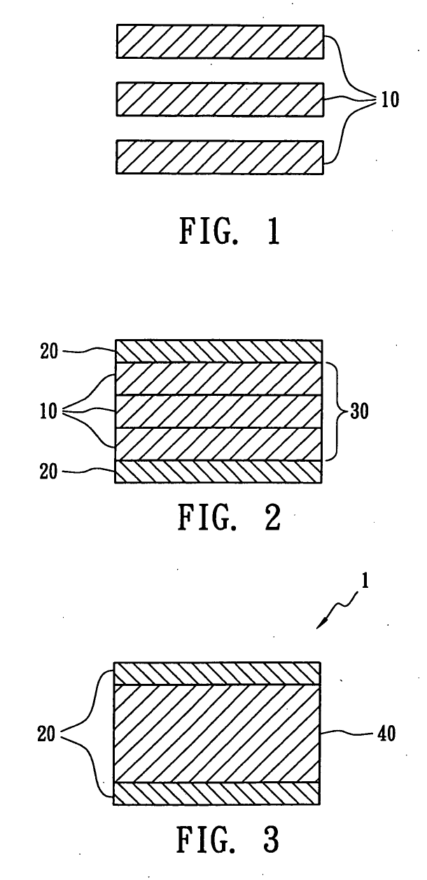

The following will describe an embodiment of the present invention including the high voltage over-current protection device and the manufacturing method thereof that is illustrated in FIGS. 1-3.

FIG. 1 illustrates the polymer substrates 10, which are formed by a partially chemical cross-linking treatment including two steps of blending and laminating. First, a first polymer of 3.85 g (containing the copolymer of glycidyl methacrylate 8% and polyethylene), a second polymer of 1.65 g (containing maleic anhydride grafted polyethylene 0.9%), carbon black (RU430) of 15.4 g, magnesium hydroxides of 11.55 g (Mg(OH)₂), talc of 6.6 g and HDPE (high density polyethylene ) of 15.95 g are fed into a blender at 160° C., 60 rpm for 9 minutes to form a polymer mixture exhibiting the properties of a first degree of cross-linking, PTC behavior and crystalline thermoplastics. Then, the polymer mixture is laminated at 150° C., 1200 psi for 0.1 hour to form the polymer substrate 10 with a second degree of cross-linking and with a thickness of 1.2 mm. During the step of blending, the first polymer, the second polymer, chemical cross-linking inhibitors and promoters are blended by controlling the process conditions (e.g., temperature, rotational speed and time) to control the reaction rate of the first polymer and the second polymer to form the polymer mixture with the first degree of cross-linking. Then, by the step of laminating, the polymer substrate 10 with the second degree of cross-linking is formed.

After that, three polymer substrates are stacked to form a stacked polymer layer 30 (refer to FIG. 2). The stacked polymer layer 30 is then sandwiched in between two nickel foils 20. Then, the stacked polymer layer 30 and the two nickel foils 20 are laminated at 150° C., 1000 psi for 0.1 hour to form a chemical cross-linking PTC substrate 40 (refer to FIG. 3), in which the two nickel foils 20 contact the stacked polymer layer 30 physically and firmly and an in-situ chemical cross-link reaction of the first functional group and the second functional group takes place. In this embodiment, the total thickness of the chemical cross-linking PTC substrate 40 and the two nickel foils 20 is 3.6 mm. Then, the chemical cross-linking PTC substrate 40 (with the two nickel foils 20) is cut by diamond saw cutting to form a plurality of chemical cross-linking PTC chips, each of them with length and width of 12.4 mm and 7.9 mm, respectively. Later, two metal terminals (note shown) are connected to the two nickel foils 20 by reflow process to form the high voltage over-current protection device 1.

To further better the chemical cross-linking degree of the chemical cross-linking PTC substrate 40, a step of heat treatment is performed which is operated at 150° C. for 10 hours. After the step of heat treatment, the chemical cross-linking PTC substrate 40 can pass a high voltage test wherein a voltage of 600V and a current of 3A are applied for one second and then are turned off for 60 seconds.

The methods and features of this invention have been sufficiently described in the above examples and descriptions. It should be understood that any modifications or changes without departing from the spirit of the invention are intended to be covered in the protection scope of the invention.

What is claimed is:

1. A manufacturing method of a high voltage over-current protection device, comprising the steps of:
providing at least one polymer mixture, which blends a first polymer with a first functional group, a second polymer with a second functional group and a conductive powder with the temperature above the softening points of the first and the second polymers, wherein the polymer mixture exhibits the properties of positive temperature coefficient (PTC) behavior and crystalline thermoplastics;
laminating the polymer mixture to form a plurality of polymer substrates;
stacking the plurality of polymer substrates to form a stacked polymer layer;
sandwiching the stacked polymer layer in between two metal foils; and
laminating the two metal foils and the stacked polymer layer to form a chemical cross-linking PTC substrate, wherein the two metal foils physically and firmly contact the stacked polymer layer and an in-situ chemical cross-linking reaction of the first functional group and the second functional group occurs.

2. The manufacturing method of a high voltage over-current protection device of claim 1, wherein the first functional group is selected from the group consisting of amino group, aldehyde group, alcohol group, epoxide group and halide group.

3. The manufacturing method of a high voltage over-current protection device of claim 1, wherein the second functional group is selected from the group consisting of acidic group, acid anhydride group and phenol group.

4. The manufacturing method of a high voltage over-current protection device of claim 1, wherein the first polymer is selected from the group consisting of an epoxide grafted polymer and an epoxide-copolymerized polymer.

5. The manufacturing method of a high voltage over-current protection device of claim 1, wherein the second polymer is selected from the group consisting of maleic anhydride grafted polyethylene, maleic anhydride copolymerized polyethylene, maleic anhydride grafted polypropylene and maleic anhydride copolymerized polypropylene.

6. The manufacturing method of a high voltage over-current protection device of claim 1, wherein the polymer mixture exhibits a first degree of cross-linking, the polymer substrates exhibit a second degree of cross-linking, and the second degree of cross-linking is larger than the first degree of cross-linking.

7. The manufacturing method of a high voltage over-current protection device of claim 1, wherein the polymer mixture is laminated at a temperature between 120° C. and 250° C.

8. The manufacturing method of a high voltage over-current protection device of claim 1, wherein the polymer mixture is laminated between 0.5 hour and 24 hours.

9. The manufacturing method of a high voltage over-current protection device of claim 1, wherein the thickness of each of the at least one polymer substrate is between 0.1 mm and 4 mm.

10. The manufacturing method of a high voltage over-current protection device of claim 1, wherein the number of the at least one polymer substrates is between 2 to 10.

11. The manufacturing method of a high voltage over-current protection device of claim 1, further comprising a step of heat treatment that enhances chemical cross-linking degree of the chemical cross-linking PTC substrate.

12. The manufacturing method of a high voltage over-current protection device of claim 11, wherein the operation time of the heat treatment is between 1 hour and 48 hours, the temperature of the heat treatment is equal to or less than 270° C.

13. The manufacturing method of a high voltage over-current protection device of claim 1, further comprising a cutting step that cuts the chemical cross-linking PTC substrate into a plurality of chemical cross-linking PTC chips.

14. The manufacturing method of a high voltage over-current protection device of claim 13, wherein the cutting step is performed by punching or diamond saw cutting.

15. A high voltage over-current protection device, comprising a chemical cross-linking PTC substrate formed by a plurality of polymer substrates; and
two metal foils connected to a power source and being configured to allow a current to flow through the chemical cross-linking PTC substrate;
wherein the voltage across every two-millimeter thickness of the chemical cross-linking PTC substrate is up to 600 V.

16. The high voltage over-current protection device of claim 15, wherein the at least one polymer substrate is formed by a first polymer with a first functional group, a second polymer with a second functional group and conductive carbon black through a partially chemical cross-linking treatment.

17. The high voltage over-current protection device of claim 16, wherein the first functional group is selected from the group consisting of amino group, aldehyde group, alcohol group, epoxide group and halide group.

18. The high voltage over-current protection device of claim 16, wherein the first polymer is selected from the group consisting of an epoxide grafted polymer and a copolymerized polymer.

19. The high voltage over-current protection device of claim 16, wherein the second functional group is selected from the group consisting of acidic group, acid anhydride group and phenol group.

20. The high voltage over-current protection device of claim 16, wherein the second polymer is selected from the group consisting of maleic anhydride grafted polyethylene, maleic anhydride copolymerized polyethylene, maleic anhydride grafted polypropylene and maleic anhydride copolymerized polypropylene.

21. The high voltage over-current protection device of claim 15, wherein the thickness of the polymer substrate is between 0.1 mm and 4 mm.

22. The high voltage over-current protection device of claim 15, wherein the number of the plurality of polymer substrates is between 2 to 10.
